(19) United States
(12) Patent Application Publication
(10) Pub. No.: US 2026/0068049 A1
(43) Pub. Date: Mar. 5, 2026

(54) FLEXIBLE PRINTED CIRCUIT AND BATTERY PACK

(71) Applicant: Guangdong Mingji Hi-Tech Electronics Co., Ltd., Dongguan (CN)

(72) Inventors: Hongzhuo ZHANG, Dongguan (CN); Jiayin LAI, Dongguan (CN); Jie GENG, Dongguan (CN); Chengfu WANG, Dongguan (CN)

(21) Appl. No.: 19/008,545

(22) Filed: Jan. 2, 2025

(30) Foreign Application Priority Data
Aug. 27, 2024 (CN) 2024220868980

(51) Int. Cl. H05K 1/11; H01M 10/42; H05K 3/00

(52) U.S. Cl. CPC H05K 1/118; H01M 10/425; H05K 3/005; H05K 2201/2018

(57) ABSTRACT

Disclosed are a flexible printed circuit and a battery pack. The flexible printed circuit comprises a flexible cable, wherein a window portion is formed in the middle of the flexible cable, and a flexible die-cutting circuit is electrically connected to the window portion. The flexible cable is a flexible flat cable. The flexible die-cutting circuit or a small flexible printed circuit is electrically connected to the window portion. The window portion is rectangular. The invention has the beneficial effect that an FCC manufactured by a new process is bendable while original FFCs and FDCs are non-bendable.

### CROSS-REFERENCE TO RELATED APPLICATIONS

The present application claims priority to Chinese Patent Application No. 2024220868980, filed on Aug. 27, 2024, the entire disclosure of which is incorporated herein by reference.

### TECHNICAL FIELD

The invention is related to the technical field of electronics, in particular to a flexible printed circuit and a battery pack.

### BACKGROUND TECHNOLOGY

In the manufacturing field of Cells Contact Systems (CCSs) for new energy battery packs, the industry typically uses traditional Flexible Printed Circuits (FPCs) for electrical signal collection. While FPCs can meet product functional requirements, they have relatively high manufacturing costs. Moreover, traditional FPCs are produced using an etching process which is not environmentally friendly, which is incongruent with the environmental protection goals of the adoption of new energy.

Therefore, there is an urgent need to develop a flexible printed circuit that has an environmentally friendly production process and is at low cost.

### SUMMARY OF INVENTION

The invention aims to solve at least one of the aforementioned technical problems to some extent.

The first objective of the invention is to propose a flexible printed circuit, which has an environmentally friendly production process and is at low cost.

The second objective of the invention is to propose a battery pack.

To achieve these objectives, the embodiments of the invention consist of a flexible printed circuit which is made up of a flexible cable 1, wherein a window portion 2 is formed in a middle of the flexible printed circuit 1, and a flexible die-cutting circuit 3 is electrically connected to the window portion 2.

In addition, the flexible printed circuit meeting the above technical solution of the invention may have the following additional technical features:

Optionally, flexible cable 1 is a flexible flat cable.

Optionally, the flexible die-cutting circuit 3 or a small flexible printed circuit is electrically connected to the window portion 2. The window portion 2 is rectangular and has a length of 4.3-8.3 mm and a width of 0.8-1.8 mm.

Optionally, the window portion 2 has a length of 6.3 mm and a width of 1.3 mm.

To achieve the above objectives, the second aspect of the invention proposes a battery pack consisting of the flexible printed circuit provided by the embodiments of the invention in the first aspect.

The invention has the following beneficial effects: an FCC manufactured by a new process is bendable whereas original FFCs and FDCs are non-bendable. Also, the production process of the FCC does not need an etching process, hence the FCC is environmentally friendly and low cost.

### BRIEF DESCRIPTION OF DRAWINGS

FIG. 1 is a schematic structural diagram of a flexible printed circuit provided by an embodiment of the invention.

FIG. 2 is a schematic structural diagram of a flexible flat cable provided by an embodiment of the invention.

FIG. 3 is a schematic structural diagram of a flexible die-cutting circuit provided by an embodiment of the invention.

### DETAILED DESCRIPTION OF EMBODIMENTS

The embodiments of the invention are described in detail below, with examples of the embodiments shown in the accompanying drawings, wherein the same or similar reference numerals throughout indicate the same or similar elements or components/elements having the same or similar functions. The embodiments described below with reference to the drawings are exemplary and explanatory only and should not be construed as limiting the scope of the invention.

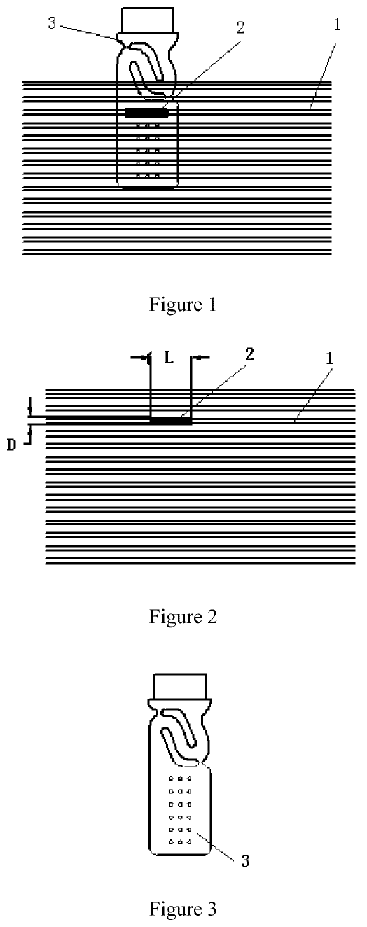

FIG. 1 is a schematic structural diagram of a flexible printed circuit provided by an embodiment of the invention. FIG. 2 is a schematic structural diagram of a flexible flat cable provided by an embodiment of the invention, and FIG. 3 is a schematic structural diagram of a flexible die-cutting circuit provided by an embodiment of the invention. As shown in FIGS. 1-3, the flexible printed circuit comprises a flexible cable 1, wherein a window portion 2 is formed in the middle of the flexible cable 1, and a flexible die-cutting circuit 3 is electrically connected to the window portion 2.

According to an embodiment of the invention, the flexible cable 1 is a flexible flat cable.

Specifically, in this embodiment, a Flexible Flat Cable (FFC) is used as the base material, a hole is punched through an insulation film of the FFC to expose one portion of a conductor to form the window portion 2, then a Flexible Die-cutting Circuit (FDC) is soldered onto window portion 2 to produce the flexible printed circuit in this embodiment. The applicant refers to this as the FCC, which stands for Flexible Flat Cable Connecting to the Flexible Die-cut Circuit, which means that the FFC is now connected to the FDC. The flexible printed circuit provided by the invention can replace traditional flexible printed circuits and adapt to electrical signal collection of CCSs of new energy battery packs and electrical signal collection of flexible circuits in electrical appliances.

It should be noted that the flexible flat cable differs from flexible cables as the flexible flat cable requires punching of a regular window portion 2 so the flexible flat cable is more reliable in the manufacturing process.

According to the flexible printed circuit provided by the invention, the FCC manufactured by a new process is bendable whereas traditional FFCs and DFCs are non-bendable, and the FCC differs from traditional FPCs merely in the manufacturing process and structural design: the manufacturing process of the FCC product is more environmentally friendly, has reduced product cost, and the FCC can replace FPC products in the future.

According to an embodiment of the invention, a flexible die-cutting circuit 3 or a small flexible printed circuit is electrically connected to the window portion 2, where the window portion 2 is rectangular and has a length of 4.3-8.3 mm and a width of 0.8-1.8 mm.

According to an embodiment of the invention, the window portion 2 has a length of 6.3 mm and a width of 1.3 mm.

Specifically, in addition to the flexible die-cutting circuit 3, a small flexible printed circuit may be connected to the window portion 2, and the size of the flexible die-cutting circuit 3 and the size of the small flexible printed circuit are both smaller than the size of the flexible flat cable, and a single flexible printed circuit or flexible die-cutting circuit cannot function for connection of a whole battery pack. Although the small flexible printed circuit will require an etching process when produced, pollution and cost are greatly reduced comparatively.

According to an embodiment of the application, the window portion 2 has a length of 6.3 mm and a width of 1.3 mm, depending on the size of contacts on the FDC. Optionally, a length range of the window portion 2 is 6.3±2 mm, and a width range of the window portion 2 is 1.3±0.5 mm. The window portion 2 should not be too large or small. If the window portion 2 is too large, the bending performance of the structure will be affected. If the window portion 2 is too small, the strength of a joint will be too low, increasing the likelihood of the connection fracturing.

Based on the above embodiment, an embodiment of the invention further provides a battery pack, comprising the flexible printed circuit according to the above embodiment.

According to the battery pack provided by the above embodiment of the invention, the FCC manufactured by a new process is bendable whereas traditional FFCs and FDCs are non-bendable, and the FCC is different from traditional FPCs only in terms of the manufacturing process and the structural design, the manufacturing process of the FCC product is more environmentally friendly, enjoys a reduced product cost, and the FCC can replace FPC products in the future.

The above embodiments are preferred implementation schemes of the application. In addition to the described embodiments, alternative implementations of the application are possible. Any obvious substitutions within the concept of the application are within the scope of protection of the application.

What is claimed is:

1. A flexible printed circuit consisting of a flexible cable (1), wherein a window portion (2) is formed in a middle of the flexible cable (1), and a flexible die-cutting circuit (3) is electrically connected to the window portion (2).

2. The flexible printed circuit according to claim 1, wherein the flexible cable (1) is a flexible flat cable.

3. The flexible printed circuit according to claim 1, wherein the flexible die-cutting circuit (3) or a small flexible printed circuit is electrically connected to the window portion (2); the window portion (2) is rectangular and has a length of 4.3-8.3 mm and a width of 0.8-1.8 mm.

4. The flexible printed circuit according to claim 3, wherein the window portion (2) has a length of 6.3 mm and a width of 1.3 mm.

5. A battery pack, comprising the flexible printed circuit according to claim 1.
